(19) United States
(12) Patent Application Publication
(10) Pub. No.: US 2022/0254652 A1
(43) Pub. Date: Aug. 11, 2022

(54) SECURING POWER SEMICONDUCTOR COMPONENTS TO CURVED SURFACES

(71) Applicant: SIEMENS AKTIENGESELLSCHAFT, München (DE)

(72) Inventors: Markus Lasch, München (DE); Claus Müller, Wolfratshausen (DE); Oliver Raab, Ortenburg, Deutschland (DE); Stefan Stegmeier, München (DE); Uwe Waltrich, Forchheim (DE)

(21) Appl. No.: 17/622,701

(22) PCT Filed: May 29, 2020
(86) PCT No.: PCT/EP2020/065051

§ 371 Date: Dec. 23, 2021

(30) Foreign Application Priority Data
Jun. 24, 2019 (DE) 10 2019 209 082.6

(51) Int. Cl. H01L 21/48; H01L 23/367; H01L 23/051; H01L 23/373

(52) U.S. Cl. CPC H01L 21/4882; H01L 23/3735; H01L 23/051; H01L 23/367

(57) ABSTRACT

The invention relates to an arrangement for a power converter (12) comprising at least one power module (1) comprising power semiconductor components (5) and a cooler (10), wherein the cooler (10) has a curved surface and the power module (1) is arranged on the surface and is connected in a positive fit to the cooler (10). The invention also relates to an associated manufacturing method as well as to a power converter with said type of arrangement and to a vehicle with a power converter.

This application is the National Stage of International Application No. PCT/EP2020/065051, filed May 29, 2020, which claims the benefit of German Patent Application No. DE 10 2019 209 082.6, filed Jun. 24, 2019. The entire contents of these documents are hereby incorporated herein by reference.

### FIELD

The present embodiments relate to an arrangement for a power converter, associated production methods, a power converter with an arrangement, and a vehicle with a power converter.

### BACKGROUND

Connecting power modules with power semiconductor components as a flat module to a cooler with planar cooling surfaces is known. However, if the cooler is present as a bent arrangement (e.g., as a round cooler) or if a pre-existing structural component is to be used as a cooling surface, significant effort is required in order to connect the power electronics. For example, milling operations are to be carried out in the cooler, or larger quantities of heat-conductive paste are to be introduced as a compensating medium, or existing thin-walled structural components are to be thickened. This thickening has a negative effect on the system weight.

If this is not possible or if the available space is limited (e.g., in the case of special superstructures in the engine area), it is advantageous if the power module (e.g., including substrate and base plate) may be constructed in the bent state. In this case, in addition to the available space, more efficient cooling may also take place, which is directly associated with the lifespan or performance of the semiconductor chip and thus the entire power module.

Power electronics variants that are concerned with a three-dimensional arrangement of the circuit or the modules are known. However, these all have in common that the power module is connected in a planar manner (e.g., not bent). In addition to these variants, there are further possibilities for achieving a three-dimensional arrangement.

### 1. Flexible Printed Circuit Board

Flexible printed circuit boards have become increasingly established as circuit carriers in recent years, since compact and complex superstructures may be realized. The circuit carrier consists mostly of epoxy, with a thickness between 25 to 100 μm and is connected on one or both sides to rolled copper with a thickness between 18 and 70 μm by an adhesive (e.g., acrylic) or directly by heat compression. The low thickness and the high crack resistance of epoxy thus makes it possible for the printed circuit board to be connected to curved surfaces (e.g., of a bent cooler). However, the limited Cu conductor track thickness, which is only conditionally suitable for power electronics applications, is disadvantageous. In addition, epoxy or polyimide is a poor heat conductor and is therefore only suitable to a limited extent as an insulator for high power densities.

### 2. MID (Mechatronic Integrated Devices)

In this case, a catalyst-filled polymer is melted at the later conductor track points by a laser (e.g., CO2 laser), and the concentration of the catalyst (e.g., palladium) is increased. A subsequent electroless plating step may grow at the catalyst and thus reinforces the conductor tracks. The polymer injection molding process results in a high degree of freedom in terms of geometries, such as bent surfaces, for example. However, the disadvantage of this method is slow growth of the conductor tracks, and therefore, only small layer thicknesses may be produced.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, power semiconductor components are secured to curved surfaces (e.g., of convexly curved A3P, coolers) in a reliable manner.

One aspect of the present embodiments involves specifying an innovative solution for realizing bent power electronics that may be constructed in a space-saving manner and provide high heat dissipation.

The present embodiments involve applying electrically conductive components or an organic/ceramic substrate for a circuit carrier to a curved surface using compression, and to connect the electrically conductive components or the organic/ceramic substrate to the surface under pressure. The application process may be carried out by known compression techniques (e.g., hydraulic compression with compensating materials, isostatic compression, etc.). In this case, it is advantageous to allow the connecting material (e.g., adhesive, solder, etc.) to harden or solidify while still under pressure. This provides that the tension in the adhesive or solder is reduced and a durable connection is created.

In this case, the electrically conductive components ideally consist of soft annealed copper or aluminum or of soft alloys that allow shaping via pressure. If entire substrates are bent, the substrates may consist of a break resistant ceramic (e.g., Si₃N₄). The ceramic may be realized as direct bonded copper (DBC) or as active metal brazing (AMB). The ceramic thickness may have a thickness from 50 μm to 2 mm (e.g., <300 μm) in order to avoid breakage and to enable low thermal resistance.

The circuit metallization may consist of copper (e.g., other metals such as Al or Mo are also possible) and possesses a thickness of approximately 10 μm to 2 mm.

In addition to the ceramic materials, organic materials, such as epoxy, polyimide, polyamide, PEEK, etc. filled with ceramic particles, for example, may be used. The connecting material may be organic in nature (e.g., epoxy, polyamide, polyimide, PEEK, etc.), ceramic in nature (e.g., ceramic adhesives, etc.), and also metallic in nature (e.g., solders, sinter adhesives, sinter pastes, etc.). Hybrid forms may also be used (e.g., organic+ceramic).

The power semiconductor components may be applied in the same process act, so that the power semiconductor components are also glued or soldered in the bent state. This provides that the tension is reduced and a durable connection is generated. In addition to wire bond silicone potting-based power modules (or wire bond epoxy resin potting), planar construction and connection technology (e.g., A3P, SiPLIT, Skin, cap technology, etc) is particularly suitable in order to transmit the compressive forces onto the substrate in a homogenous manner. This significantly reduces the risk of prior damage or destruction (e.g., a wire breakage, chip breakages, etc.).

If organic substrates are used (e.g., insulation consisting of organic material), a curvature introduced previously may simplify the pressure lamination described previously. One further aspect of the present embodiments involves the surface that is to be molded later already being introduced during production or being subsequently generated subtractively (e.g., by grinding, laser ablation, etc.) in the case of an organic-based substrate. A permanent or releasable connection to the later molded part (e.g., a bent cooler) may then be produced by suitable joining technology.

The present embodiments include an arrangement for a power converter, having at least one power module, that has power semiconductor components, and a cooler. The cooler has a curved surface, and the power module is arranged on the surface and is connected to the cooler in a cohesive manner.

The present embodiments offer the advantage that power modules may also be firmly secured to curved surfaces.

In one development, the cohesive connection may be formed by a connecting layer.

In one further embodiment, the connecting layer may be an insulating film, a solder or an adhesive.

In one further specification, the power semiconductor components may be curved in the same way as the power module.

In one further configuration, the power module may have conductor tracks curved in the same way as the surface that contact the power semiconductor components and in which cavities for receiving the power semiconductor components are formed such that the power semiconductor components are not arranged in a bent manner.

In one further configuration, the power module may have a ceramic substrate curved in the same way as the power module, on which ceramic substrate the power semiconductor components are arranged.

In one further configuration, the power module may have a thick copper substrate, where the side of the thick copper substrate facing away from the power semiconductor components is configured to be curved to correspond to the surface of the cooler.

The present embodiments include a method for producing an arrangement according to the present embodiments. An insulating film, conductor tracks, first solder layers, power semiconductor components, second solder layers, and a second circuit carrier are stacked on the surface of the cooler and are subsequently pressure laminated.

The present embodiments include a method for producing an arrangement according to the present embodiments with the acts: stacking an insulating film and the conductor tracks on the surface of the cooler; pressure laminating the stack; forming the cavities in the conductor tracks; arranging a first solder layer and the power semiconductor components in the cavities; stacking second solder layers and the second circuit carrier on the power semiconductor components; and pressure laminating the stack.

The present embodiments also include a method for producing an arrangement according to the present embodiments with the acts: modifying an underside of a thick copper substrate into the shape of the surface of the cooler; stacking an insulating film and the power module on the surface of the cooler; and pressure laminating the stack.

The present embodiments also include a power converter (e.g., a converter) with an arrangement according to the present embodiments.

A converter (e.g., an inverter) denotes a power converter that generates, from an alternating voltage or direct voltage, an alternating voltage that has changed in frequency and amplitude. Converters are often designed as AC/DC-DC/AC converters or DC/AC converters, where an output alternating voltage is generated from an input alternating voltage or an input direct voltage via a direct voltage intermediate circuit and clocked semiconductors.

The present embodiments also include a vehicle (e.g., an aircraft) with a power converter according to the invention for an electric or hybrid electric drive.

A vehicle is understood as any kind of means of locomotion or transportation, be it known or unknown. An aircraft is a flying vehicle.

In one development of the invention, the aircraft can be an airplane.

The airplane can have an electric motor which is supplied with electrical energy by way of the power converter and a propellor which can be set in rotation by the electric motor.

Further special features and advantages of the invention shall become clear in the subsequent explanations of a plurality of exemplary embodiments using schematic drawings.

### BRIEF DESCRIPTION OF THE DRAWINGS

FIG. 1 shows a sectional view of an arrangement of a first exemplary embodiment;

FIG. 2 shows a further sectional view of an arrangement of the first exemplary embodiment;

FIG. 3 shows a further sectional view of an arrangement of the first exemplary embodiment;

FIG. 4 shows a sectional view of an arrangement of a second exemplary embodiment;

FIG. 5 shows a further sectional view of an arrangement of the second exemplary embodiment;

FIG. 6 shows a further sectional view of an arrangement of the second exemplary embodiment;

FIG. 7 shows a sectional view of an arrangement of a third exemplary embodiment;

FIG. 8 shows a further sectional view of an arrangement of the third exemplary embodiment;

FIG. 9 shows a sectional view of an arrangement of a fourth exemplary embodiment;

FIG. 10 shows a further sectional view of an arrangement of the fourth exemplary embodiment;

FIG. 11 shows a further sectional view of an arrangement of the fourth exemplary embodiment;

FIG. 12 shows a block diagram of one embodiment of a power converter with a power module; and

FIG. 13 shows an embodiment of an aircraft with an electrical thrust generation unit.

### DETAILED DESCRIPTION

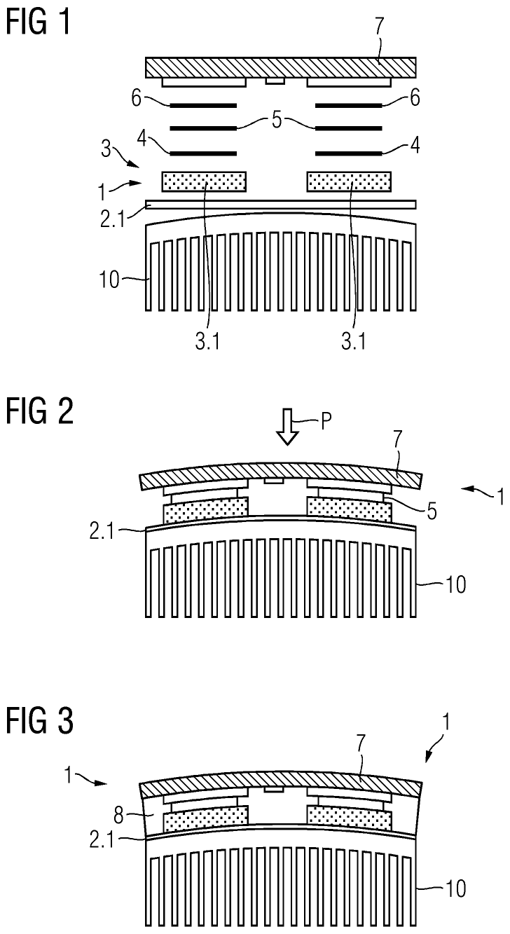

FIGS. 1-3 show sectional views of a power module 1 of a first exemplary embodiment. FIG. 1 shows an initial state before a pressure lamination; FIG. 2 shows the state after pressure lamination; and FIG. 3 shows a filled power module 1. The following components of the power module 1 are arranged in a stacked manner on a cooler 10 with a one-dimensional curved surface: an insulating film 2.1 (e.g., B-stage material, pre-crosslinked polymer); a first circuit carrier 3 with conductor tracks 3.1 (e.g., made of ductile copper or aluminum); a first solder layer 4 (e.g., solder preforms); power semiconductor components 5; a second solder layer 6; and a second circuit carrier 7 (e.g., a printed circuit board (PCB) with ductile copper).

As a result of soldering under pressure (indicated by the arrow P) and heat, as shown in FIG. 2, all components are laminated in a bent manner on the cooler 1 and harden under pressure (e.g., in the case of B-staging materials) or solidify (e.g., solder). A final filling using an insulating material 8 (also referred to as “underfill”), as represented in FIG. 3, provides the insulation and an additional mechanical fixing.

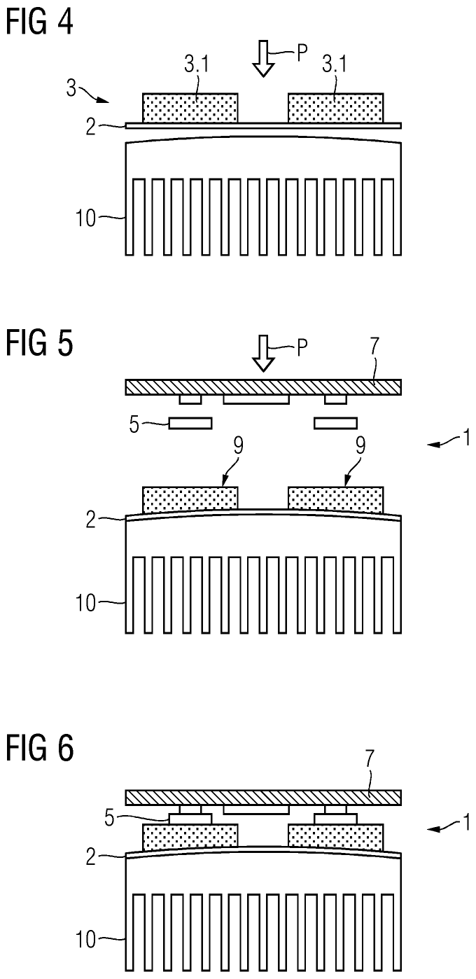

FIGS. 4 to 6 show cross sections of a power module 1 in a second exemplary embodiment, where pressure laminating the first circuit carrier 3 (e.g., below the power semiconductor components 5) onto the one-dimensional curved cooler 10 first takes place by the connecting layer 2, as indicated in FIGS. 4 and 5 with the arrow P.

Cavities 9 are subsequently milled in the first circuit carrier 3 with conductor tracks 3.1 of the first circuit carrier 3, as represented in FIG. 5, which have the advantage that a corresponding lower boundary lies on a planar, non-curved plane. It is therefore provided that the overlying, partially not represented layers, such as the first solder layer 4, power semiconductor components 5, the second solder layer 6, and the second circuit carrier 7, may be pressure laminated on a planar plane in a second act, as shown in FIG. 6, and the power semiconductor components 5 do not have to be bent.

This approach reduces the risk of possible semiconductor damage that is caused by the curvature being too high.

For the sake of clarity, the insulating material 8 is not drawn in this exemplary embodiment but is configured analogous to FIG. 3.

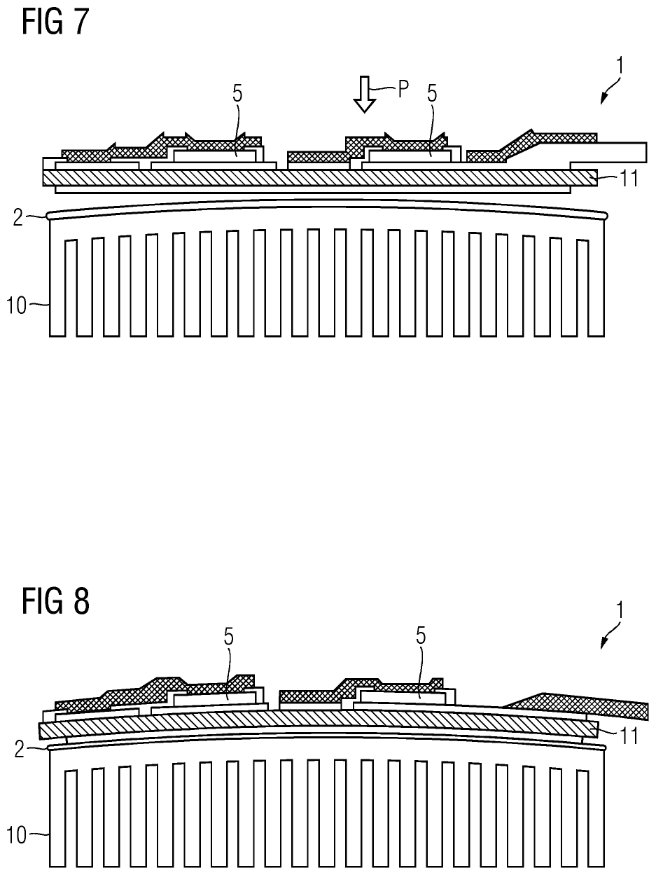

FIGS. 7 and 8 show cross sections of a third exemplary embodiment of a power module 1, where FIG. 7 shows the initial state before a pressure lamination and FIG. 8 shows the state afterwards. A power module 1 with Si₃N₄ ceramic carrier 11 and planar construction and connection technology is placed above the cooler 10 with a one-dimensional curved surface. A connecting layer 1 (e.g., a solder or an adhesive) is applied in between. As a result of soldering under pressure, as indicated in FIG. 7 by the arrow P, the ceramic carrier 11 is bent and the overlying power semiconductor components 5 with planar construction and connection technology are also bent.

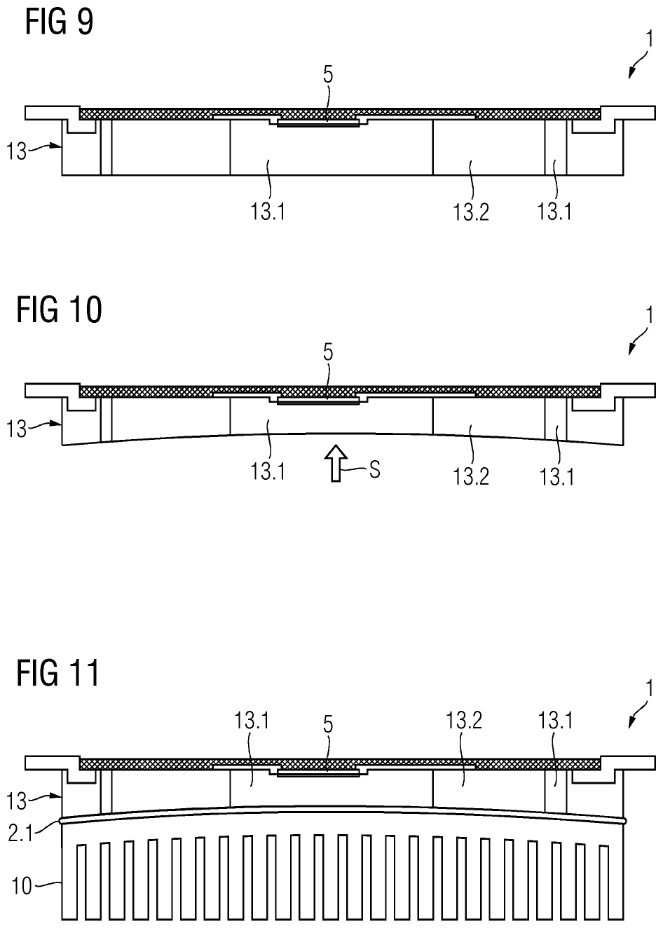

FIGS. 9 to 11 show a cross section of a fourth exemplary embodiment of a power module 1 with an organic thick copper substrate 13 (e.g., insulation, organic material) that is arranged on a cooler 10 with a one-dimensional curved surface. The organic substrate 13 consists of a plurality of millimeter-thick Cu parts 13.1 (e.g., >250 μm thick) that are embedded in a mold material 13.2. The power semiconductor components 5 are already located on the thick copper substrate 13 (e.g., soldered, sintered, glued, etc.) and are additionally contacted with a planar construction and connection technology.

A subtractive process (e.g., grinding, milling, etc.), as indicated in FIG. 10 by the arrow S, eliminates the topography to be molded later. Molding the topography may take place both before and after applying the power semiconductor components 5. The thick copper substrate 13 is subsequently connected to the cooler 10 by an electrically insulating material (e.g., insulating film 2.1) via a pressure lamination process, as represented in FIG. 11. The insulating film 2.1 may be made of epoxy with ceramic particles, for example.

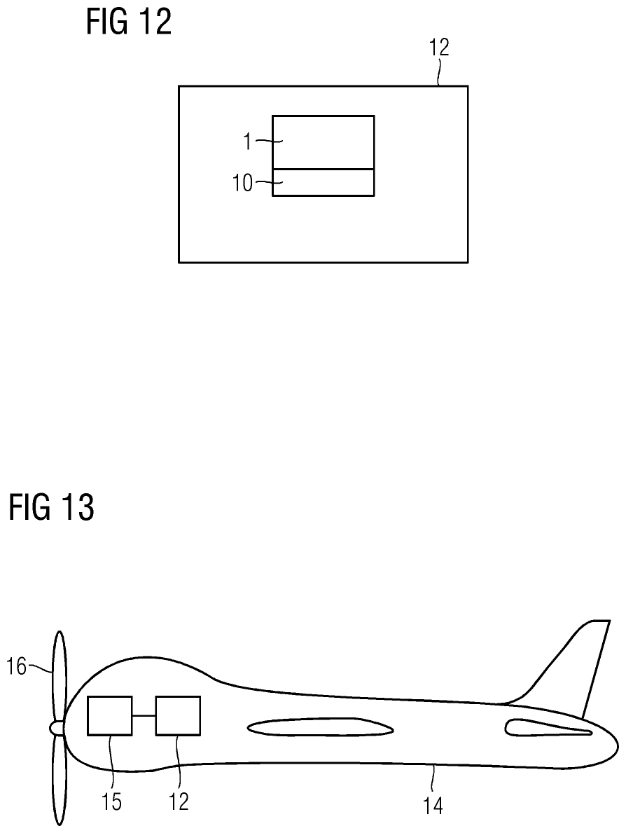

FIG. 12 shows a block diagram of a power converter 12 (e.g., a converter) with a power module 1 that, according to the present embodiments, is joined to a cooler 10 according to the representations from FIGS. 1 to 11.

FIG. 13 shows an electric or hybrid electric aircraft 14 (e.g., an airplane) with a power converter 12 according to FIG. 12 that supplies an electric motor 15 with electrical energy. The electric motor 15 drives a propellor 16. Both are part of an electrical thrust generation unit.

Despite the fact that the invention has been illustrated and described in greater detail by way of the exemplary embodiments, the invention is not limited by the examples disclosed, and other variations may be derived from this by the person skilled in the art, without departing from the scope of protection of the invention.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. An arrangement for a power converter, the arrangement comprising:
at least one power module that includes power semiconductor components; and
a cooler,
wherein the cooler has a curved surface, and the at least one power module is arranged on the curved surface and is connected to the cooler in a cohesive manner.

2. The arrangement of claim 1, wherein the cohesive connection is formed by a connecting layer.

3. The arrangement of claim 2, wherein the connecting layer is an insulating film, a solder, or an adhesive.

4. The arrangement of claim 1, wherein the power semiconductor components are bent with same curvature as the at least one power module.

5. The arrangement of claim 1, wherein the at least one power module has conductor tracks curved in a same way as the curved surface that contacts the power semiconductor components and in which cavities for receiving the power semiconductor components are formed such that the power semiconductor components are arranged in a planar manner.

6. The arrangement of claim 1, wherein the at least one power module has a ceramic carrier curved in a same way as the at least one power module, the power semiconductor components being arranged on the ceramic carrier.

7. The arrangement of claim 1, wherein the at least one power module has a thick copper substrate, and
wherein a side of the thick copper substrate facing away from the power semiconductor components is configured to be curved to correspond to the curved surface of the cooler.

8. A method for producing an arrangement for a power converter, the arrangement comprising at least one power module that includes power semiconductor components and a cooler, wherein the cooler has a curved surface, and the at least one power module is arranged on the curved surface and is connected to the cooler in a cohesive manner, the method comprising:
stacking an insulating film, conductor tracks, first solder layers, the power semiconductor components, second solder layers, and a second circuit carrier on the curved surface of the cooler; and
pressure laminating the stack.

9. The method of claim 8, wherein the at least one power module has the conductor tracks curved in a same way as the curved surface that contacts the power semiconductor components and in which cavities for receiving the power semiconductor components are formed such that the power semiconductor components are arranged in a planar manner, and
wherein the stacking and the pressure laminating of the stack comprises:
stacking the insulating film and the conductor tracks on the curved surface of the cooler;
pressure laminating the stack of the insulating film and the conductor tracks on the curved surface of the cooler;
forming the cavities in the conductor tracks;
arranging a first solder layer of the first solder layers and the power semiconductor components in the cavities;
stacking second solder layers and the second circuit carrier on the power semiconductor components; and
pressure laminating the stack.

10. The method of claim 8, wherein the at least one power module has a thick copper substrate, and a side of the thick copper substrate facing away from the power semiconductor components is configured to be curved to correspond to the curved surface of the cooler, and
wherein the method further comprises:
modifying an underside of the thick copper substrate into a shape of the curved surface of the cooler; and
stacking the insulating film and the power module on the curved surface of the cooler, and
wherein pressure laminating the stack comprises pressure laminating the stack of the insulating film and the power module on the curved surface of the cooler.

11. A power converter comprising:
an arrangement comprising:
at least one power module that includes power semiconductor components; and
a cooler,
wherein the cooler has a curved surface, and the at least one power module is arranged on the curved surface and is connected to the cooler in a cohesive manner.

12. A vehicle comprising:
a power converter for an electric or hybrid electric drive, the power converter comprising:
an arrangement comprising:
at least one power module that includes power semiconductor components; and
a cooler,
wherein the cooler has a curved surface, and the at least one power module is arranged on the curved surface and is connected to the cooler in a cohesive manner.

13. The vehicle of claim 12, wherein the vehicle is an aircraft.

14. The vehicle of claim 13, wherein the aircraft is an airplane.

15. The vehicle of claim 14, further comprising:
an electric motor that is supplied with electrical energy via the power converter; and
a propellor that is settable in rotation by the electric motor.
